(19) United States
(12) Patent Application Publication
(10) Pub. No.: US 2025/0063806 A1
(43) Pub. Date: Feb. 20, 2025

(54) METHOD FOR PRODUCING FET STRUCTURE

(71) Applicant: HUAWEI TECHNOLOGIES CO., LTD., Shenzhen (CN)

(72) Inventors: Yijian CHEN, Shenzhen (CN); Krishna Kumar Bhuwalka, Leuven (BE)

(21) Appl. No.: 18/936,703

(22) Filed: Nov. 4, 2024

Related U.S. Application Data
(63) Continuation of application No. PCT/CN2022/090965, filed on May 5, 2022.

(51) Int. Cl. H01L 21/8238; H01L 29/66

(52) U.S. Cl. CPC H01L 21/823842; H01L 21/823878; H01L 29/66439

(57) ABSTRACT

The present disclosure relates to a method for producing a field-effect transistor, FET, structure (10, 10′, 10″, 10′″). The method comprises the steps of: a) generating a first structure on a substrate (11), the first structure comprising a first layer stack (12a), a second layer stack (12b), and a wall (15) between the first layer stack (12a) and the second layer stack (12b), wherein the first layer stack (12a) and the second layer stack (12b) each comprise one or more first material layers (13) and two or more second material layers (14) stacked in alternating manner, and wherein the wall (15) is electrically non-conductive; b) removing the one or more first material layers (13) of the first layer stack (12a) to generate one or more cavities in the first layer stack (12a); c) etching into one side of the wall (15) through the one or more cavities in the first layer stack (12a) to recess the side of the wall (15), thereby generating a vertical cavity (19) between the first layer stack (12a) and the recessed side of the wall (15); and d) filling the cavities in the first layer stack (12a) and the vertical cavity (19) with gate dielectric materials and gate metals (17).

### CROSS-REFERENCE TO RELATED APPLICATIONS

This application is a continuation of International Application No. PCT/CN2022/090965, filed on May 5, 2022, the disclosure of which is hereby incorporated by reference in its entirety.

### TECHNICAL FIELD

The present disclosure relates to a method for producing a field-effect-transistor (FET) structure and to a FET structure obtainable by said method.

### BACKGROUND

Metal-oxide semiconductor field-effect transistors (MOSFETs) are the main semiconductor components in various devices, such as microprocessors and memory chips. A fin field-effect transistor (FinFET) is a special type of MOSFET with a fin shaped channel that is surrounded by a gate on two or three sides. Due to this gate design, FinFETs provide a better scalability than conventional planar MOSFETs.

A nanosheet field-effect transistor (NS FET) is another type of MOSFET that comprises horizontally stacked nanosheets that form the channels of the transistor. In a NS FET, the gate can completely surround the nanosheet channels forming a so-called gate-all-around (GGA) device, i.e. a transistor device in which the gate is placed on all four sides of the channel(s). Such gate-all-around devices are often seen as next device architecture that allows further scaling of complementary metal-oxide semiconductor (CMOS) devices beyond the limitations of FinFETs.

Forksheet nanosheet devices have been proposed as an extension of nanosheet devices. In a forksheet FET the vertical nanosheets are separated into a pMOS and an nMOS side by a vertical dielectric isolation. The forksheet FET design allows for further area scaling and provides more room for optimizing the active width of the device. However, short-channel effects in forksheet FETs may result in performance losses. In particular, due to the dielectric isolation in a forksheet FET, it is typically not possible to completely surround the nanosheet channels of the forksheet FET with the gate on all four sides. Thus, forksheet FETs do not allow for a gate-all-around design which potentially limits the further scaling of these devices.

### SUMMARY

In view of the above, this disclosure aims to provide an improved method for processing a FET structure and an improved FET structure obtainable by said method, which overcomes the above mentioned limitations and disadvantages.

These and other objectives are achieved by the solution of this disclosure as described in the independent claims. Advantageous implementations are further defined in the dependent claims.

A first aspect of this disclosure provides a method for producing a field-effect transistor, FET, structure, comprising the steps of: a) generating a first structure on a substrate, the first structure comprising a first layer stack, a second layer stack, and a wall between the first layer stack and the second layer stack, wherein the first layer stack and the second layer stack each comprise one or more first material layers and two or more second material layers stacked in alternating manner, and wherein the wall is electrically non-conductive; b) removing the one or more first material layers of the first layer stack to generate one or more cavities in the first layer stack; c) etching into one side of the wall through the one or more cavities in the first layer stack to recess the side of the wall, thereby generating a vertical cavity between the first layer stack and the recessed side of the wall; and d) filling the cavities in the first layer stack and the vertical cavity with gate dielectric materials and gate metals.

This provides the advantage that a FET structure with a forksheet nanosheet design is provided in which the gate can completely surround some or all of the nanosheet channels. Thus, the FET structure provides a gate-all-round design which can reduce performance losses and allow for further scaling of the FET structure.

In an implementation form of the first aspect, the gate dielectric materials and gate metals surround some or all of the second material layers of the first layer stack on four sides.

In particular, the gate dielectric materials and gate metals also cover the second material layers on the side that is facing the wall. This is typically not possible in a conventional forksheet FET where there is no gap between the nanosheet layers and the dielectric barrier.

In an implementation form of the first aspect, the wall is formed from a dielectric material.

This provides the advantage that the wall is formed from an electrically non-conductive material. For instance, the wall can be formed from a nitride material, such as silicon nitride, Si₃N₄.

In an implementation form of the first aspect, the step of etching into the side of the wall comprises an isotropic etching of the wall.

This provides the advantage that the wall can be efficiently recessed from the first layer stack such that the gate materials can completely surround the remaining material layers of the first layer stack. Thus, the FET structure can have a gate-all-around design.

Isotropic etching means that the etching properties do not depend on the etching direction, i.e. the etching rate is essentially the same for all etching directions. In particular, the isotropic etching of the side of the wall generates a characteristic surface profile of the wall (Baluster shape). This Baluster profile of the wall is visible in the processed FET structure and provides a characteristic fingerprint of the method.

In an implementation form of the first aspect, the first and the second material layers are nanolayers.

The FET structure can be a nanosheet FET, in particular a forksheet nanosheet FET.

In an implementation form of the first aspect, the one or more first material layers are one or more silicon germanium, SiGe, layers; and the two or more second material layers are two or more silicon, Si, layers.

In an implementation form of the first aspect, the one or more first material layers are one or more silicon, Si, layers, and the two or more second material layers are two or more silicon germanium, SiGe, layers.

In an implementation form of the first aspect, the gate metals comprise n-type work function metals.

This provides the advantage that a nMOS side of the FET structure can be formed by surrounding the remaining layers of the first layer stack with the n-type work function metals.

In an implementation form of the first aspect, a first part of the cavities in the first layer stack is filled with n-type work function metals and a second part of the cavities in the first layer stack is filled with p-type work function metals.

This provides the advantage that both a nMOS and a pMOS structure can be formed on one side of the wall of the FET structure. Thus, the FET structure can be a complementary FET structure that comprises nMOS and pMOS structures stacked on top of each other.

In an implementation form of the first aspect, the method further comprises: e) removing the one or more first or the two or more second material layers of the second layer stack to generate one or more cavities in the second layer stack; f) etching into the other side of the wall through the one or more cavities in the second layer stack to recess the other side of the wall from the second layer stack, thereby generating a further vertical cavity between the second layer stack and the recessed other side of the wall; and g) filling the cavities in the second layer stack an the further vertical cavity with further gate dielectric materials and further gate metals.

This achieves the advantage that the gate can also completely surround some or all of the nanosheet channels on the other side of the structure. Thus, the FET structure can be a forksheet FET structure with a gate-all-around design on both sides (e.g., nMOS and pMOS side) of the structure.

In an implementation form of the first aspect, the steps e)-g) are carried out simultaneously with the steps b)-d), respectively.

For example, the further gate dielectric materials and/or the further gate metals can be identical to the gate dielectric materials and/or the gate metals used to fill the cavities in the first layer stack.

It is, however, also possible that only the steps e) and f) are carried out simultaneously with the steps b) and c), respectively.

In an implementation form of the first aspect, the further gate dielectric materials and the further gate metals surround some or all of the remaining material layers of the second layer stack on four sides.

In particular, the further gate dielectric materials and further gate metals also cover the remaining material layers of the second stack on the side that is facing the wall. The etching (step f) can again be carried out by an isotropic etching of the wall that generates the characteristic Baluster shape. Here, remaining material layers may refer to the material layers of the second layer stack which were not removed in step e).

In an implementation form of the first aspect, the further gate metals are p-type work function metals.

This provides the advantage that a pMOS side of the FET structure can be formed by surrounding the remaining layers of the second layer stack with the p-type work function metals.

In an implementation form of the first aspect, a first part of the cavities in the second layer stack is filled with n-type work function metals and a second part of the cavities in the second layer stack is filled with p-type work function metals.

This provides the advantage that both a nMOS and a pMOS structure can also be formed on the other side of the wall of the FET structure.

In an implementation form of the first aspect, the substrate is or comprises doped silicon, Si.

In an implementation form of the first aspect, the method further comprises: doping a source region of the substrate, and doping a drain region of the substrate.

This provides the advantage that source and drain contacts of the FET structure can be generated.

In an implementation form of the first aspect, the step of forming the first structure on the substrate comprises: forming a layer stack on the substrate, wherein the layer stack comprises one or more first material layers and two or more second material layers stacked in an alternating manner; forming a trench in the layer stack by etching, thereby generating the first layer stack and the second layer stack; and filling the trench with one or more electrically non-conductive materials, thereby generating the wall.

The layer stack can be formed by subsequently depositing the first material layers and the second material layers on the substrate using a suitable deposition technique, such as chemical vapour deposition (CVD). The trench position can be defined by an opening in a hard mask on the layer stack and the trench can be formed by etching into the layer stack.

A second aspect of this disclosure provides a field-effect transistor, FET, structure, obtainable by the method according to the first aspect of the disclosure.

The FET structure can be a nanosheet structure or a nanosheet FET structure, in particular a forksheet nanosheet FET structure.

Such a FET structure produced with the method of the first aspect of the disclosure shows clear “fingerprints” of that method. For instance, by etching into one or both sides of the wall, using an isotropic etching process, a characteristic Baluster shape is generated on one or both sides of the wall. This characteristic wall profile can be visible in the processed structure. For example, a structural check by means of a cross-section TEM (transmission electron microscope) image can reveal this characteristic Baluster shape.

### BRIEF DESCRIPTION OF DRAWINGS

The above described aspects and implementation forms will be explained in the following description of specific embodiments in relation to the enclosed drawings, in which

FIGS. 1A-D show steps of a method for producing a FET structure according to an embodiment of this disclosure;

FIGS. 2A-E show steps of a method for producing a FET structure according to an embodiment of this disclosure;

FIG. 3 shows a schematic diagram of a FET structure according to an embodiment of this disclosure; and

FIG. 4 shows a schematic diagram of a FET structure according to an embodiment of this disclosure.

### DETAILED DESCRIPTION OF EMBODIMENTS

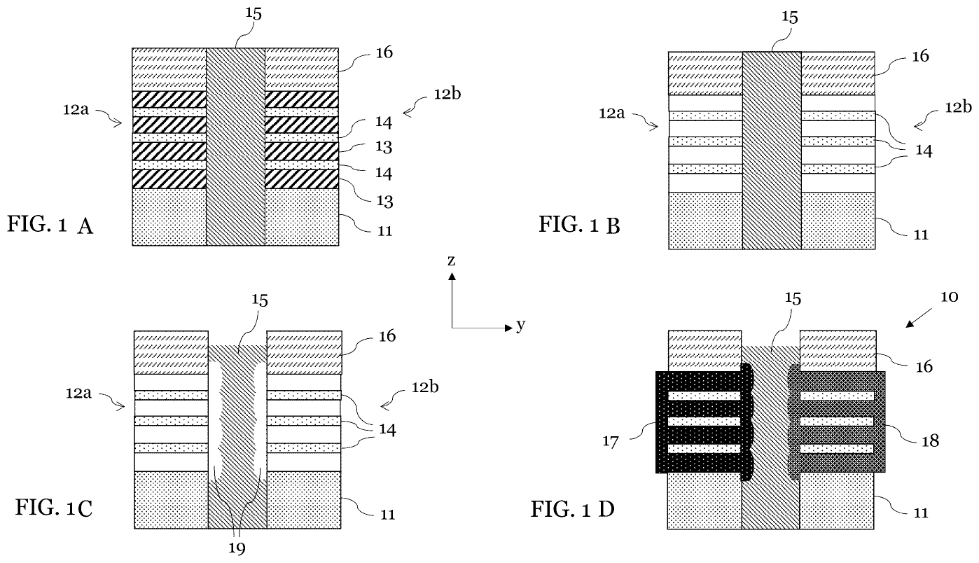

FIGS. 1A-D show steps of a method for producing a FET structure 10 according to an embodiment of this disclosure.

Thereby, FIGS. 1A-D show the processing of a single FET structure. Nevertheless, the method may be used to produce a plurality of FET structures in parallel on the same substrate 11.

The method comprises, as shown in FIG. 1A, generating a first structure on a substrate 11. This first structure comprises a first layer stack 12a, a second layer stack 12b, and a wall 15 between the first layer stack 12a and the second layer stack 12b. Thereby, the first layer stack 12a and the second layer stack 12b each comprise one or more first material layers 13 and two or more second material layers 14 stacked in alternating manner. In particular, the material layers 13, 14 are vertically stacked along a z-direction and extend along an x-direction, perpendicular to the cross-sectional view in the y-z-plane as indicated by the schematic coordinate system in FIGS. 1A-D.

For example, the first structure can be formed by (not shown in FIGS. 1A-D): forming a layer stack on the substrate 11, wherein the layer stack comprises the one or more first material layers 13 and the two or more second material layers 14 stacked in the alternating manner; and forming a trench in the layer stack by etching, thereby separating the layer stack in the first layer stack 12a and the second layer stack 12b. The trench can subsequently be filled with one or more electrically non-conductive materials, thereby generating the wall 15. For instance, the trench can be etched in the layer stack via a gap in an etch mask 16, e.g. a hardmask.

The wall 15 is electrically non-conductive. For example, the wall 15 is formed from a dielectric material, for instance a nitride such as silicon nitride (Si₃N₄). The wall can have a thickness of 15-20 nm (along the width-direction). For example, a part of the wall 15 can penetrate the substrate 11 as shown in the FIGS. 1A-B.

Some or all of the first and the second material layers 13, 14 can be nanolayers, i.e. layers with a nanoscale thickness. For example, the first material layers 13 can be silicon germanium (SiGe) layers; and the second material layers can be silicon (Si) layers. However, the order of the layers 13, 14 can also be reversed, i.e. the first material layers 13 can be Si layer and the second material layers 14 can be SiGe layers.

The substrate 11 can be a Si substrate or a SOI (silicon on insulator) substrate. In particular, the substrate 11 can comprise doped Si. For instance, a source and a drain region of the substrate 11 is at least partially formed by the doped Si. In this regard, the method can comprise the further step of: doping a source region of the substrate 11, and doping a drain region of the substrate 11. This doping of the substrate 11 can be carried out prior to forming the first structure on the substrate 11.

The method further comprises, as shown in FIG. 1B, the step of removing the one or more first material layers 13 to generate one or more cavities in the layer stacks 12a, 12b.

The first material layers 13 can be removed with a suitable dry or wet etching process.

In FIG. 1B, the first material layers 13 are removed in both the first and the second layer stack 12a, 12b. However, it is also possible to only remove the first material layers 13 in the first layer stack 12a, while keeping the first material layers 13 of the second layer stack 12b intact. For instance, the first (or second) material layers 13, 14 of the second layer stack 12b could then be removed in a later processing step.

As shown in FIG. 1C, the method further comprises the step of etching into the sides of the wall 15 through the one or more cavities in the layer stacks 12a, 12b to recess the sides of the wall. Thereby, a respective vertical cavity 19 between each layer stack 12a, 12b and the recessed sides of the wall 15 is generated.

In case the first material layers 13 were only removed from the first layer stack 12a and not the second layer stack 12b, then only one side of the wall 15—namely the side facing the first layers stack 12a—is etched through the one or more cavities in the first layer stack 12a and, thus, only one vertical cavity 19 is generated between the first layer stack 12a and the recessed side of the wall 15.

In particular, the step of etching into the side(s) of the wall 15 comprises an isotropic etching of the wall 15. Isotropic etching means that the etching properties do not depend on the etching direction, i.e. the etching rate is essentially the same for all etching directions. This generates a characteristic, Baluster shaped surface profile on the side(s) of the wall 15, as shown in FIG. 1C.

The etching of the wall can be a selective etching step, i.e. there is no etch-attack to the material layers 14, the gate and inner spacers.

For instance, the etching of the wall can be carried out by a suitable wet etching process, e.g. with an HF solution.

As shown in FIG. 1D, the method further comprises the step of filling the cavities in the layer stacks 12a, 12b and the vertical cavities 19 with gate dielectric materials and/or gate metals.

For instance, the cavities in the first layer stack 12a as well as the cavity 19 between first layer stack 12a and one side of the wall can be filled with certain gate dielectric materials and gate metals, in particular n-type work function metals, while the cavities in the second layer stack 12b as well as the cavity 19 between first layer stack 12a and the other side of the wall can be filled with further gate dielectric materials and gate metals, in particular p-type work function metals.

Both the gate metals and the further gate metals can comprise a blend of metals or a single type of metal. The gate metals and the further gate metals can be N and P high-k metals, respectively.

In particular, the gate dielectric materials and the further gate dielectrics can be identical and can be deposited in a single step. In particular, the gate dielectric materials are formed to completely surround the second material layers 14 of the first and second layer stack 12a, 12b. Then, the gate metals and the further gate metals can be deposited subsequently or simultaneously on the gate dielectric materials.

In the alternative case (not shown in FIGS. 1A-D), where the first material layers 13 was only removed from the first layer stack 12a and cavities were only formed in the first layer stack 12a and between the first layer stack 12a and the recessed side of the wall 15, only the cavities on one side of the wall are filled with the gate dielectric materials and gate metals, e.g. n-type work function metals.

With the process shown in FIGS. 1A-D, a FET structure 10 can be obtained which comprises a nMOS side and a pMOS side. Thereby, the second material layers 14 of the first layer stack 12a can form channels on the nMOS side of the FET structure 10 and the second material layers 14 of the second layer stack 12b can form channels on the pMOS side of the FET structure 10. The channels can be Si channels. The gate dielectrics and gate metals can surround some or all of the channels on the nMOS side on four sides. The same is true for the further gate dielectrics and further gate metals that can completely surround some or all of the channels on the pMOS side. Thus, the FET structure 10 can be a gate-all-around (GAA) FET structure with a forksheet nanosheet design. In particular, the structure 10 is a Baluster Nanosheet (BNS) MOSFET structure, i.e. a NS MOSFET with a dielectric wall which has a characteristic Baluster profile.

The etch mask 16, which is shown in all FIGS. 1A-D, could also be removed after forming the first structure on the substrate 11 (FIG. 1A) or after filling the cavities in the layer stacks 12a, 12b with the gate dielectric materials and/or gate metals 17, 18 (FIG. 1D) or at some point between these steps.

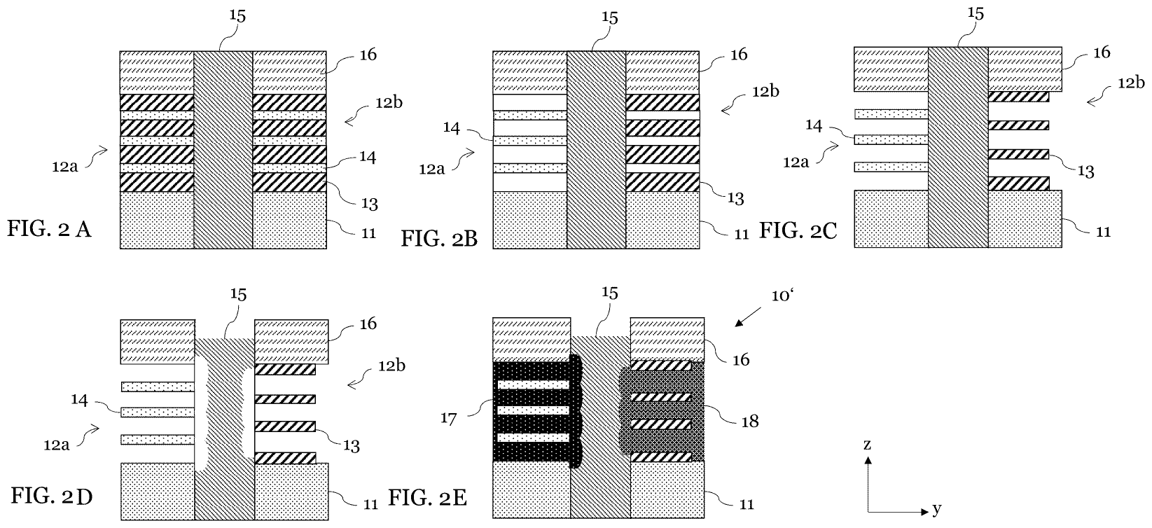

FIGS. 2A-E show steps of a method for producing a FET structure 10′ according to an embodiment of this disclosure.

The method shown in FIGS. 2A-E differs from the method shown in FIGS. 1A-D in that different material layers 13, 14 of the first and the second layer stack 12a, 12b, respectively, are removed such that the resulting FET structure 10′ comprises channels of different materials on both sides of the wall 15.

As shown in FIG. 2A, the method again starts with generating the first structure on the substrate 11. Subsequently, as shown in FIG. 2B, the first material layers 13 of the first layer stack 12a and the second material layers 14 of the second layer stack 12b are removed. This can be done in two subsequent selective etching steps. The selective removal of the respective material layers 13, 14 in the layer stacks 12a, 12b can be facilitated by respective N/P protection masks e.g. to protect the side that is not being etched.

For instance, the first material layers 13 are SiGe layers and the second material layers are Si layers. Both material layers 13, 14 can be nanolayers. However, the SiGe layers 13 can be thicker than the Si layers 14. To reduce the thickness of the remaining first material layers 13 in the second layer stack 12b, the method can comprise a step of selective trimming of the first material layers 13 in the second layer stack 12b, as shown in FIG. 2C. The trimming can be performed by via etching of the remaining first material layers 13.

Subsequently, as shown in FIG. 2D, the method comprises the step of etching into the sides of the wall 15 through the cavities in the layer stacks 12a, 12b to recess the sides of the wall 15 and generate the vertical cavities 19 between the layer stacks 12a, 12b and the wall 15. This generates the characteristic Baluster shape of the wall 15, which is in this case asymmetric between both sides of the wall 15 due to the fact that the remaining material layers 13, 14 on both sides of the wall 15 are vertically offset.

FIG. 2E shows the final step of filling the cavities in the layer stacks 12a, 12b and the vertical cavities 19 with gate dielectric materials and/or gate metals. Thereby, the cavities in the first layer stack 12a can be filled with n-type work function metals and the cavities in the second layers stack 12b can be filled with p-type work function metals.

In this way, a FET structure 10′ can be generated which can have channels formed from different materials on the n-side and on the p-side, namely Si channels on the n-side and SiGe channels on the p-side.

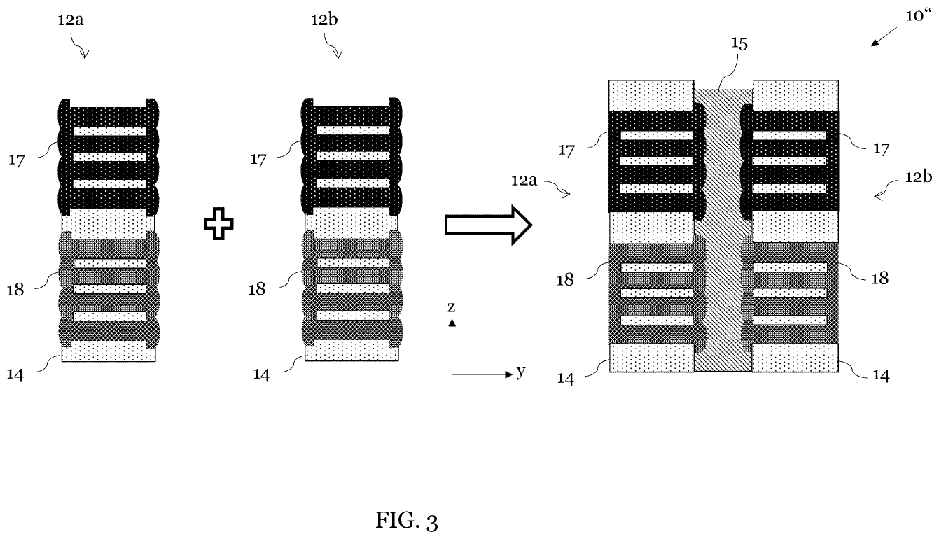

FIG. 3 shows a schematic diagram of a FET structure 10″ according to an embodiment of this disclosure.

The FET structure 10″ shown in FIG. 3 comprises two layer stacks 12a, 12b which are separated by the dielectric wall 15. Each of these layer stacks 12a, 12b, which are also individually depicted in FIG. 3, comprises cavities that are filled with different work function metals, e.g. n-type work function metals 17 and p-type work function metals 18.

Thus, the resulting FET structure 10″ is a complementary FET (CFET) structure that has nMOS and a pMOS sections stacked on top of each other on both sides of the wall 15. In particular, the FET structure 10″ is a Baluster nanosheet CFET (BNS CFET).

The layer stacks 12a, 12b shown in FIG. 3 also comprises material layers of different thickness. For instance, a material layer in-between the nMOS and the pMOS section can be thicker than the material layers within said sections in order to physically separate the nMOS and pMOS sections.

The FET structure 10″ shown in FIG. 3 can be generated with the method shown in FIGS. 1A-D, wherein the respective cavities in the layer stacks 12a, 12b can be subsequently filled with the different gate metals 17, 18.

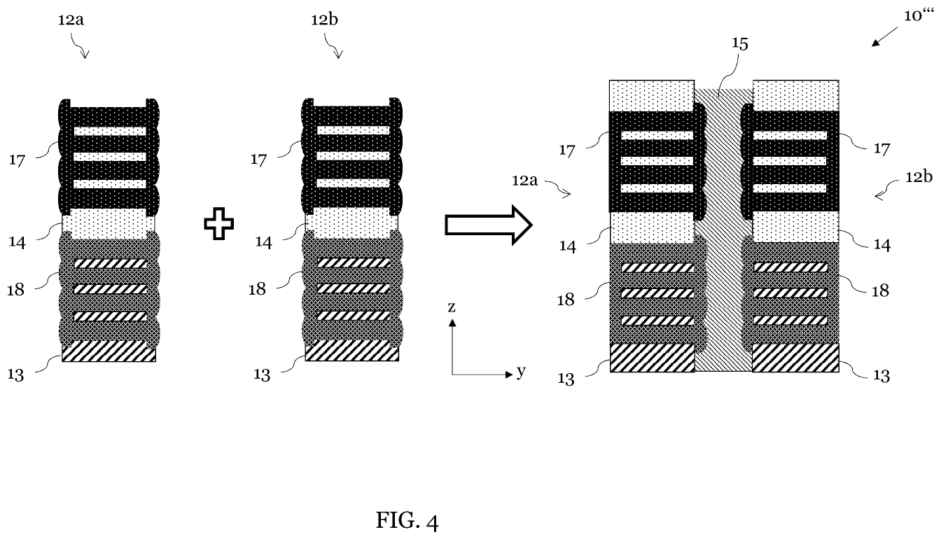

FIG. 4 shows a schematic diagram of a FET structure 10′″ according to an embodiment of this disclosure.

The FET structure 10′″ is similar to the structure 10″ shown in FIG. 3 and comprises nMOS and the pMOS sections on both sides of the wall 15. However, in the structure 10′″ shown in FIG. 4, different material layers were removed from the layer stacks 12a, 12b in the pMOS and the nMOS section. Thus, the respective nMOS sections, for example, comprise Si channels and the respective pMOS sections comprise SiGe channels.

In particular, the above FET structures 10, 10′, 10″, 10′″ allow for an improved device performance due to: (i) a better effective width as compared to three-gate forksheet like devices (i.e., forskheet FETs with a gate on three sides of the channel); and (ii) better short-channel effects due to a better gate coverage on all sides while at the same time providing standard cell scaling with the wall 15.

The FET structures 10, 10′, 10″, 10′″ may be comprised by a processor or processing circuitry (not shown) configured to perform, conduct or initiate various operations. The processing circuitry may comprise hardware and/or the processing circuitry may be controlled by software. The hardware may comprise analog circuitry or digital circuitry, or both analog and digital circuitry. The digital circuitry may comprise components such as application-specific integrated circuits (ASICs), field-programmable arrays (FPGAs), digital signal processors (DSPs), or multi-purpose processors. The device may further comprise memory circuitry, which stores one or more instruction(s) that can be executed by the processor or by the processing circuitry, in particular under control of the software. For instance, the memory circuitry may comprise a non-transitory storage medium storing executable software code which, when executed by the processor or the processing circuitry, causes the various operations of the device to be performed. In one embodiment, the processing circuitry comprises one or more processors and a non-transitory memory connected to the one or more processors.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

What is claimed is:

1. A method for producing a field-effect transistor, FET, structure (10, 10′, 10″, 10″″), comprising the steps of:
a) generating a first structure on a substrate (11), the first structure comprising a first layer stack (12a), a second layer stack (12b), and a wall (15) between the first layer stack (12a) and the second layer stack (12b), wherein the first layer stack (12a) and the second layer stack (12b) each comprise one or more first material layers (13) and two or more second material layers (14) stacked in alternating manner, and wherein the wall (15) is electrically non-conductive;
b) removing the one or more first material layers (13) of the first layer stack (12a) to generate one or more cavities in the first layer stack (12a);
c) etching into one side of the wall (15) through the one or more cavities in the first layer stack (12a) to recess the side of the wall (15), thereby generating a vertical cavity (19) between the first layer stack (12a) and the recessed side of the wall (15); and
d) filling the cavities in the first layer stack (12a) and the vertical cavity (19) with gate dielectric materials and gate metals (17).

2. The method of claim 1,
wherein the gate dielectric materials and gate metals (17) surround some or all of the second material layers (14) of the first layer stack (12a) on four sides.

3. The method of claim 1,
wherein the wall (15) is formed from a dielectric material.

4. The method of claim 1,
wherein the step of etching into the side of the wall (15) comprises an isotropic etching of the wall.

5. The method of claim 1,
wherein the first and the second material layers (13, 14) are nanolayers.

6. The method of claim 1,
wherein the one or more first material layers (13) are one or more silicon germanium, SiGe, layers; and wherein the two or more second material layers (14) are two or more silicon, Si, layers.

7. The method of claim 1,
wherein the one or more first material layers (13) are one or more silicon, Si, layers, and wherein the two or more second material layers (14) are two or more silicon germanium, SiGe, layers.

8. The method of claim 1,
wherein the gate metals (17) comprise n-type work function metals.

9. The method of claim 1,
wherein a first part of the cavities in the first layer stack (12a) is filled with n-type work function metals and a second part of the cavities in the first layer (12b) stack is filled with p-type work function metals.

10. The method of claim 1, wherein the method further comprises:
e) removing the one or more first or the two or more second material layers (13, 14) of the second layer stack (12b) to generate one or more cavities in the second layer stack (12b);
f) etching into the other side of the wall (15) through the one or more cavities in the second layer stack (12b) to recess the other side of the wall (15) from the second layer stack (12b), thereby generating a further vertical cavity (19) between the second layer stack (12b) and the recessed other side of the wall (15); and
g) filling the cavities in the second layer stack an the further vertical cavity (19) with further gate dielectric materials and further gate metals (18).

11. The method of claim 10,
wherein the steps e)-g) are carried out simultaneously with the steps b)-d), respectively.

12. The method of claim 10,
wherein the further gate dielectric materials and the further gate metals (18) surround some or all of the remaining material layers (13, 14) of the second layer stack (12b) on four sides.

13. The method of claim 10,
wherein the further gate metals (18) are p-type work function metals.

14. The method of claim 10,
wherein a first part of the cavities in the second layer stack (12b) is filled with n-type work function metals and a second part of the cavities in the second layer stack (12b) is filled with p-type work function metals.

15. The method of claim 1,
wherein the substrate (11) is or comprises doped silicon, Si.

16. The method of claim 1, further comprising:
doping a source region of the substrate (11), and doping a drain region of the substrate (11).

17. The method of claim 1, wherein forming the first structure on the substrate comprises:
forming a layer stack on the substrate, wherein the layer stack comprises one or more first material layers (13) and two or more second material layers (14) stacked in an alternating manner;
forming a trench in the layer stack by etching, thereby generating the first layer stack (12a) and the second layer stack (12b); and
filling the trench with one or more electrically non-conductive materials, thereby generating the wall (15).

18. A field-effect transistor (FET) structure (10, 10′, 10″, 10″″), obtainable by the method according to claim 1.
